(19) United States
(12) Patent Application Publication
(10) Pub. No.: US 2026/0036902 A1
(43) Pub. Date: Feb. 5, 2026

(54) SEMICONDUCTOR PHOTORESIST COMPOSITIONS AND METHODS OF FORMING PATTERNS USING THE COMPOSITIONS

(71) Applicant: SAMSUNG SDI CO., LTD., Yongin-si (KR)

(72) Inventors: Dong Wan RYU, Suwon-si (KR); Joonhee HAN, Suwon-si (KR); Sumin JANG, Suwon-si (KR); Soobin LIM, Suwon-si (KR); Kyungmog KIM, Suwon-si (KR); Hyun LEE, Suwon-si (KR); Jimin KIM, Suwon-si (KR); Yunju CHAE, Suwon-si (KR)

(21) Appl. No.: 19/239,706

(22) Filed: Jun. 16, 2025

(30) Foreign Application Priority Data
Aug. 1, 2024 (KR) 10-2024-0102729

(51) Int. Cl. G03F 7/004; H01L 21/027

(52) U.S. Cl. CPC G03F 7/0043; G03F 7/0041; H01L 21/0274

(57) ABSTRACT

Provided are a semiconductor photoresist composition including an organometallic compound; a salt compound including an anion represented by Chemical Formula 1; and a solvent, and a method of forming patterns using the same. The details of Chemical Formula 1 are as described in the specification.

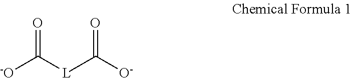

### CROSS-REFERENCE TO RELATED APPLICATION

The present application claims priority to and the benefit of Korean Patent Application No. 10-2024-0102729, filed on Aug. 1, 2024, in the Korean Intellectual Property Office, the entire content of which is hereby incorporated by reference.

### BACKGROUND

### 1. Field

Embodiments of this disclosure relate to semiconductor photoresist compositions and methods of forming patterns using the same.

### 2. Description of the Related Art

EUV (extreme ultraviolet) lithography has been paid attention to as one technology for manufacturing a next generation semiconductor device. EUV lithography is a pattern-forming technology using an EUV ray having a wavelength of 13.5 nm as an exposure light source. According to EUV lithography, an extremely fine pattern (e.g., less than or equal to 20 nm) may be formed in an exposure process during manufacture of a semiconductor device.

EUV lithography has been realized through development of compatible photoresists which can be utilized at a spatial resolution of less than or equal to 16 nm. Currently, efforts to satisfy or improve insufficient specifications of traditional chemically amplified (CA) photoresists such as a resolution, a photospeed, and feature roughness (which may also be referred to as a line edge roughness or LER) for next generation devices are being made.

An intrinsic image blurring due to an acid catalyzed reaction in these polymer-type photoresists limits a resolution in small feature sizes, which has been present in electron beam (e-beam) lithography for a long time. Chemically amplified (CA) photoresists are designed for high sensitivity, but because their general elemental makeups reduce light absorbance of the photoresists at a wavelength of 13.5 nm and thus decrease their sensitivity, chemically amplified (CA) photoresists may at least partially have more difficulties under an EUV exposure.

CA photoresists may have difficulties in the small feature sizes due to roughness issues, and line edge roughness (LER) of CA photoresists experimentally turns out to be increased, as a photospeed is decreased partially due to an essence of acid catalyst processes. Accordingly, a high-performance photoresist is required or would be beneficial in a semiconductor industry because of these defects and problems of the CA photoresists.

In order to overcome the aforementioned drawbacks of chemically amplified (CA) organic photosensitive composition, an inorganic photosensitive composition has been researched. Inorganic photosensitive compositions are mainly used for negative tone patterning having resistance against removal by a developer composition due to chemical modification through nonchemical amplification mechanism. The inorganic composition contains an inorganic element having a higher EUV absorption rate than hydrocarbon and thus may secure sensitivity through the nonchemical amplification mechanism, and is less sensitive with respect to a stochastic effect and thus has low line edge roughness and the small number of defects.

Inorganic photoresists based on peroxopolyacids of tungsten mixed with tungsten, niobium, titanium, and/or tantalum have been reported as radiation sensitive materials for patterning.

These materials are effective for patterning large pitches for bilayer configuration as far ultraviolet (deep UV), X-ray, and electron beam sources. More recently, if (e.g., when) cationic hafnium metal oxide sulfate (HfSOx) materials along with a peroxo complexing agent have been used to image a 15 nm half-pitch (HP) through projection EUV exposure, impressive performance has been obtained. This system exhibits the highest performance of a non-CA photoresist and has a practicable photospeed near to a requirement or utility for an EUV photoresist. However, the hafnium metal oxide sulfate material having the peroxo complexing agent has a few practical drawbacks. First, these materials are coated in a mixture of corrosive sulfuric acid/hydrogen peroxide and have insufficient shelf-life stability. Second, a structural change thereof for performance improvement as a composite mixture is not easy. Third, development should be performed in a TMAH (tetramethylammonium hydroxide) solution at an extremely high concentration of 25 wt % and/or the like.

Recently, active research has been conducted on molecules containing tin that have excellent absorption of extreme ultraviolet rays. As for an organotin polymer among them, alkyl ligands are dissociated by light absorption or secondary electrons produced thereby, and are crosslinked with adjacent chains through oxo bonds and thus enable the negative tone patterning which may not be removed by an organic developer. This organotin polymer exhibits greatly improved sensitivity as well as maintains a resolution and line edge roughness, but the patterning characteristics should be additionally improved for commercial availability.

### SUMMARY

Some example embodiments of the present disclosure provide a semiconductor photoresist composition capable of implementing excellent sensitivity and LER characteristics.

Some example embodiments provide a method of forming patterns using the semiconductor photoresist composition.

A semiconductor photoresist composition according to some example embodiments includes an organometallic compound, a salt compound including an anion represented by Chemical Formula 1, and a solvent.

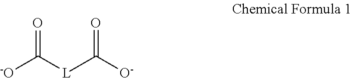

In Chemical Formula 1,
L is a single bond (e.g., a single covalent bond), a substituted or unsubstituted C1 to C10 alkylene group, a substituted or unsubstituted C2 to C10 alkenylene group, a substituted or unsubstituted C3 to C20 cycloalkylene group, a substituted or unsubstituted C3 to C20 cycloalkenylene group, a substituted or unsubstituted C6 to C30 arylene group, a substituted or unsubstituted C2 to C30 heteroarylene group, or a combination thereof.

A method of forming patterns according to some example embodiments includes forming an etching-objective layer on a substrate, coating the semiconductor photoresist composition on the etching-objective layer to form a photoresist layer, patterning the photoresist layer to form a photoresist pattern and etching the etching-objective layer using the photoresist pattern as an etching mask.

The semiconductor photoresist composition according to some example embodiments can provide a photoresist pattern having improved sensitivity and LER characteristics.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIGS. 1A-1E are cross-sectional views illustrating a method of forming patterns using a semiconductor photoresist composition according to some example embodiments.

### DETAILED DESCRIPTION

Hereinafter, referring to the drawings, embodiments are described in more detail. In the following description of embodiments of the present disclosure, well-known functions or constructions will not be described in order to clarify the subject matter of the present disclosure.

In order to clearly illustrate the subject matter of the present disclosure, certain description and relationships may be omitted, and throughout the disclosure, the same or similar configuration elements are designated by the same reference numerals. Also, because the size and thickness of each configuration shown in the drawings may be arbitrarily shown for better understanding and ease of description, the present disclosure is not necessarily limited thereto.

In the drawings, the thickness of layers, films, panels, regions, and/or the like, may be enlarged for clarity. In the drawings, the thickness of a part of layers or regions, and/or the like, may be exaggerated for clarity. It will be understood that if (e.g., when) an element such as a layer, film, region, or substrate is referred to as being “on” another element, it can be directly on the other element or intervening elements may also be present.

As used herein, “substituted” refers to replacement of a hydrogen atom by deuterium, a halogen, a hydroxy group, a carboxyl group, a thiol group, a cyano group, a nitro group, —NRR′ (wherein, R and R′ are each independently hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein, R, R′, and R″ are each independently hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, a C1 to C20 sulfide group, or a combination thereof. “Unsubstituted” refers to non-replacement of a hydrogen atom by another substituent and remaining of the hydrogen atom.

As used herein, if (e.g., when) a definition is not otherwise provided, “alkyl group” refers to a linear or branched aliphatic hydrocarbon group. The alkyl group may be “saturated alkyl group” without any double bond or triple bond.

The alkyl group may be a C1 to C8 alkyl group. For example, the alkyl group may be a C1 to C7 alkyl group, a C1 to C6 alkyl group, or a C1 to C5 alkyl group. For example, the C1 to C5 alkyl group may be a methyl group, an ethyl group, a propyl group, an isopropyl group, an n-butyl group, an isobutyl group, a sec-butyl group, a tert-butyl group, or a 2,2-dimethylpropyl group.

As used herein, if (e.g., when) a definition is not otherwise provided, “cycloalkyl group” refers to a monovalent cyclic aliphatic hydrocarbon group.

The cycloalkyl group may be a C3 to C8 cycloalkyl group, for example, a C3 to C7 cycloalkyl group, or a C3 to C6 cycloalkyl group. For example, the cycloalkyl group may be a cyclopropyl group, a cyclobutyl group, a cyclopentyl group, or a cyclohexyl group, but is not limited thereto.

As used herein, “aryl group” refers to a substituent in which all atoms in the cyclic substituent have a p-orbital and these p-orbitals are conjugated and may include a monocyclic or fused ring polycyclic functional group (e.g., rings sharing adjacent pairs of carbon atoms).

As used herein, “heteroaryl group” may refer to an aryl group including at least one heteroatom selected from among N, O, S, P, and Si. Two or more heteroaryl groups may be linked by a sigma bond directly, or if (e.g., when) the heteroaryl group includes two or more rings, the two or more rings may be fused. If (e.g., when) the heteroaryl group is a fused ring, each ring may include one to three heteroatoms.

As used herein, unless otherwise defined, “alkenyl group” refers to an aliphatic unsaturated alkenyl group including at least one double bond as a linear or branched aliphatic hydrocarbon group.

As used herein, unless otherwise defined, “alkynyl group” refers to an aliphatic unsaturated alkynyl group including at least one triple bond as a linear or branched aliphatic hydrocarbon group.

A semiconductor photoresist composition according to some example embodiments is described.

The semiconductor photoresist composition according to some example embodiments includes an organometallic compound, a salt compound including an anion represented by Chemical Formula 1, and a solvent.

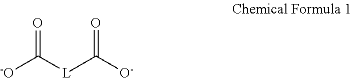

In Chemical Formula 1,
L is a single bond (e.g., a single covalent bond), a substituted or unsubstituted C1 to C10 alkylene group, a substituted or unsubstituted C2 to C10 alkenylene group, a substituted or unsubstituted C3 to C20 cycloalkylene group, a substituted or unsubstituted C3 to C20 cycloalkenylene group, a substituted or unsubstituted C6 to C30 arylene group, a substituted or unsubstituted C2 to C30 heteroarylene group, or a combination thereof.

The semiconductor photoresist composition according to the present disclosure is a composition that includes an organometallic compound and an onium dicarboxylate-based additive and a solvent and is capable of producing dicarboxylic acid upon exposure, wherein dicarboxylic acid is produced only in the exposed region to promote crosslinking with the organometallic compound, thereby increasing the sensitivity to ultraviolet rays and improving pattern roughness in a pattern formed using the composition.

In embodiments, the dicarboxylate ion state of the onium dicarboxylate-based additive is maintained in the non-exposed region, and the dicarboxylate ion can be easily removed by the phenomenon, thereby improving scum and bridge defects (e.g., thereby reducing a likelihood, degree, or occurrence of scum and/or bridge defects).

For example, embodiments of forming crosslinking with an organotin compound is schematically illustrated in Scheme 1.

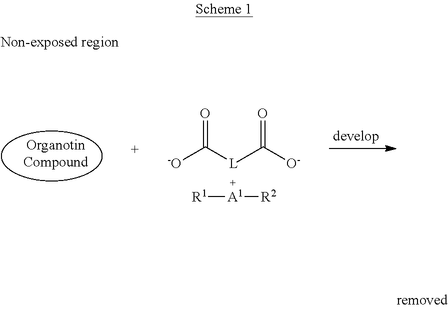

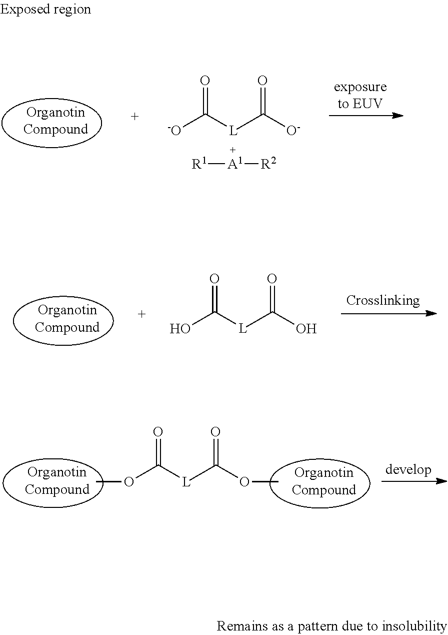

For example, L may be a single bond (e.g., a single covalent bond), a substituted or unsubstituted methylene group, a substituted or unsubstituted ethylene group, a substituted or unsubstituted propylene group, a substituted or unsubstituted butylene group, a substituted or unsubstituted pentylene group, a substituted or unsubstituted ethenylene group, a substituted or unsubstituted cyclopentylene group, a substituted or unsubstituted cyclohexylene group, a substituted or unsubstituted cyclopentenylene group, a substituted or unsubstituted cyclohexenylene group, a substituted or unsubstituted cyclopentadienylene group, a substituted or unsubstituted cyclohexadienylene group, a substituted or unsubstituted phenylene group, a substituted or unsubstituted furanylene group, a substituted or unsubstituted thiophenylene group, or a substituted or unsubstituted pyridinylene group.

As an example, the anion represented by Chemical Formula 1 may be selected from among those listed in Group I.

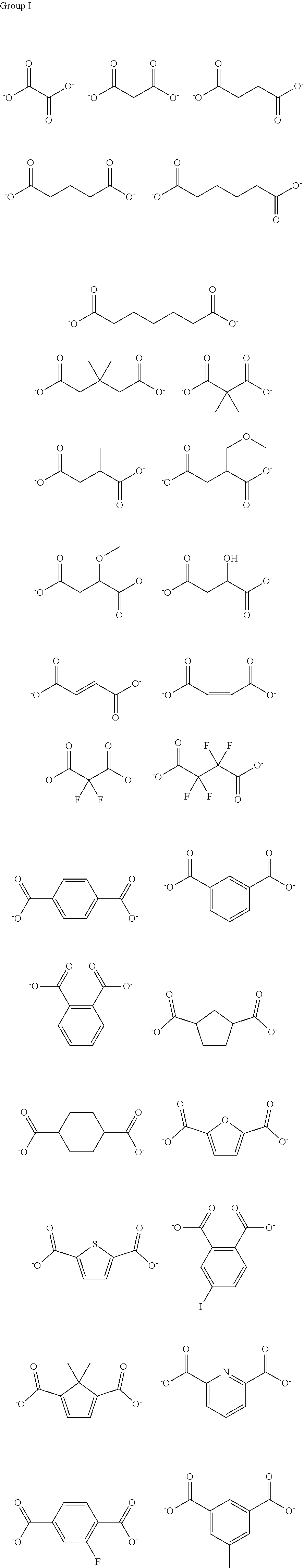

In embodiments, the salt compound may include a cation represented by Chemical Formula 2A or Chemical Formula 2B.

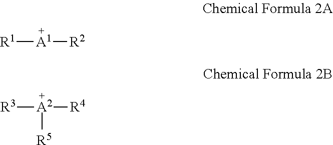

In Chemical Formula 2A and Chemical Formula 2B,
A¹ is F, Cl, Br, or I,
A² is O, S, Se, or Te, and
R¹ to R⁵ are each independently halogen, a hydroxy group, an ester group, a substituted or unsubstituted C1 to C20 alkyl group, a substituted or unsubstituted C1 to C20 alkoxy group, a substituted or unsubstituted C3 to C20 cycloalkyl group, a substituted or unsubstituted C2 to C20 aliphatic unsaturated organic group including one or more double bonds or triple bonds, a substituted or unsubstituted C6 to C30 aryl group, or a combination thereof.

A¹ may be I.

A² may be S.

For example, R¹ to R⁵ may each independently be a substituted or unsubstituted C6 to C20 aryl group.

For example, Chemical Formula 2A may be represented by Chemical Formula 2A-1, and
Chemical Formula 2B may be represented by Chemical Formula 2B-1.

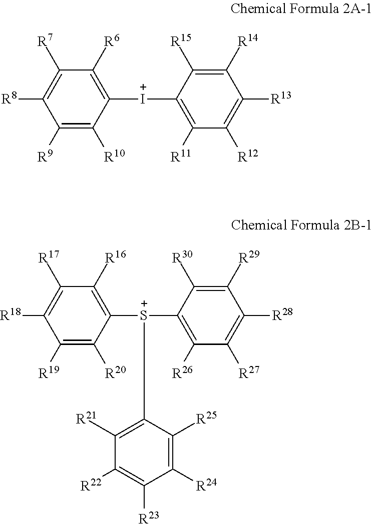

In Chemical Formula 2A-1 and Chemical Formula 2B-1,
R⁶ to R³⁰ are each independently hydrogen, a halogen, a hydroxy group, an ester group, a substituted or unsubstituted C1 to C20 alkyl group, a substituted or unsubstituted C1 to C20 alkoxy group, a substituted or unsubstituted C6 to C30 aryl group, or a combination thereof.

The substituted or unsubstituted C6 to C20 aryl group may be for example substituted or unsubstituted phenyl group, a substituted or unsubstituted biphenyl group, a substituted or unsubstituted naphthyl group, a substituted or unsubstituted tolyl group, a substituted or unsubstituted anthracenyl group, or a substituted or unsubstituted phenanthrenyl group.

The salt compound may be selected from among the compounds listed in Group 1.

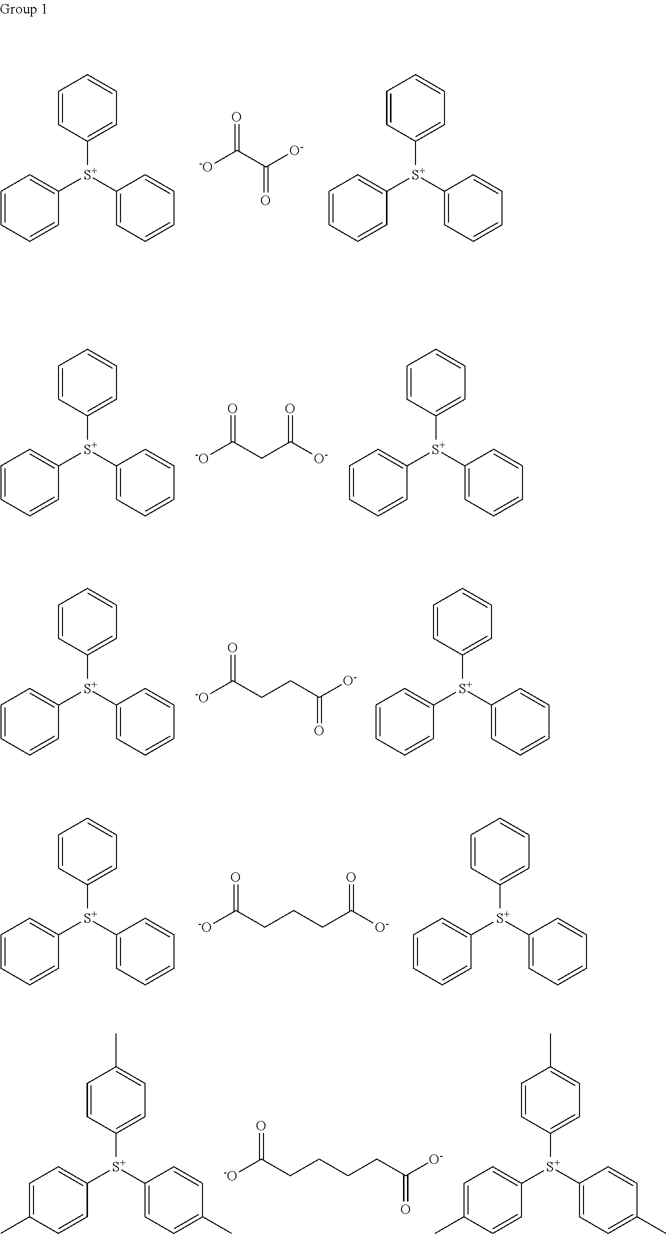

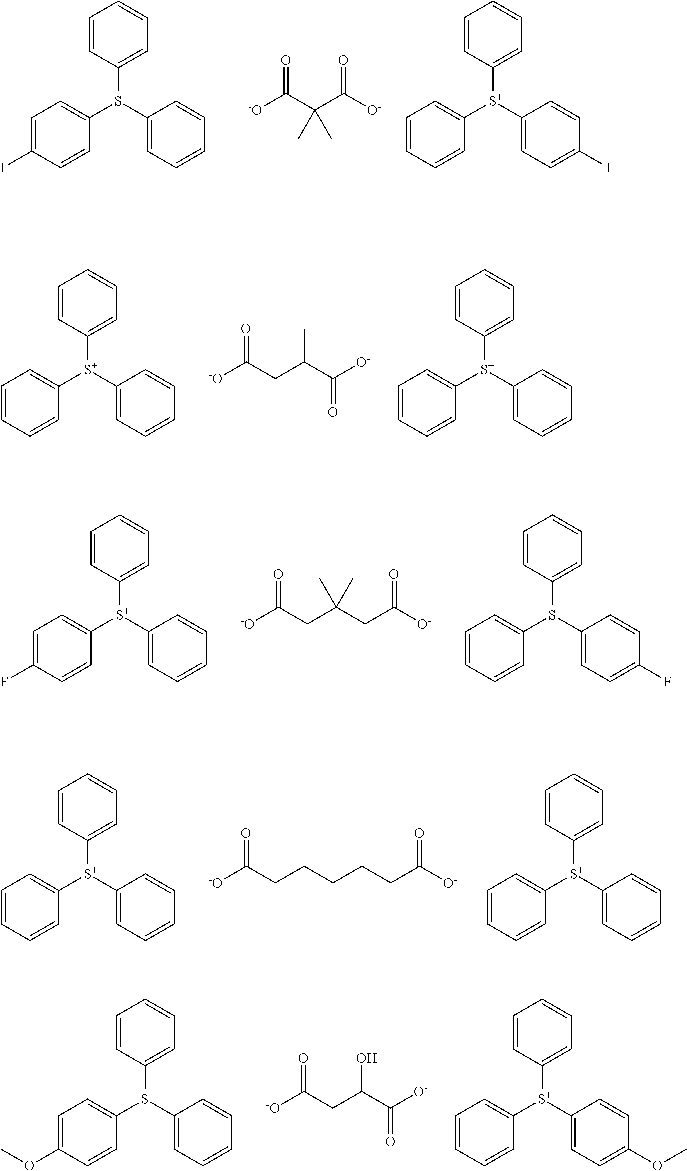

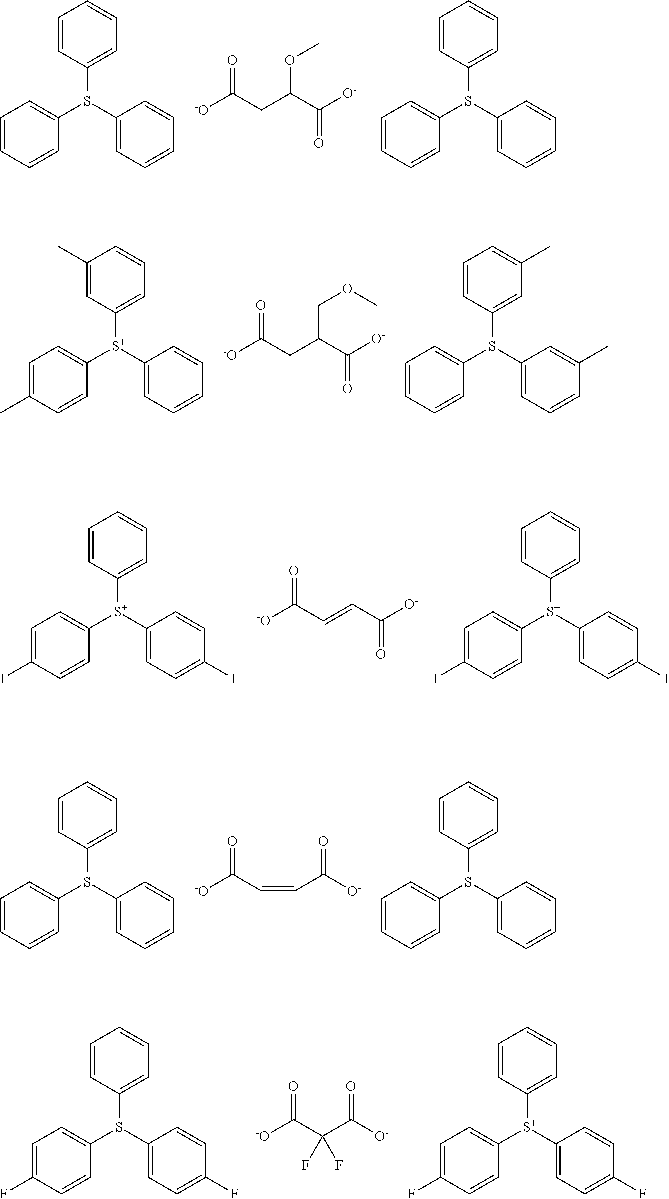

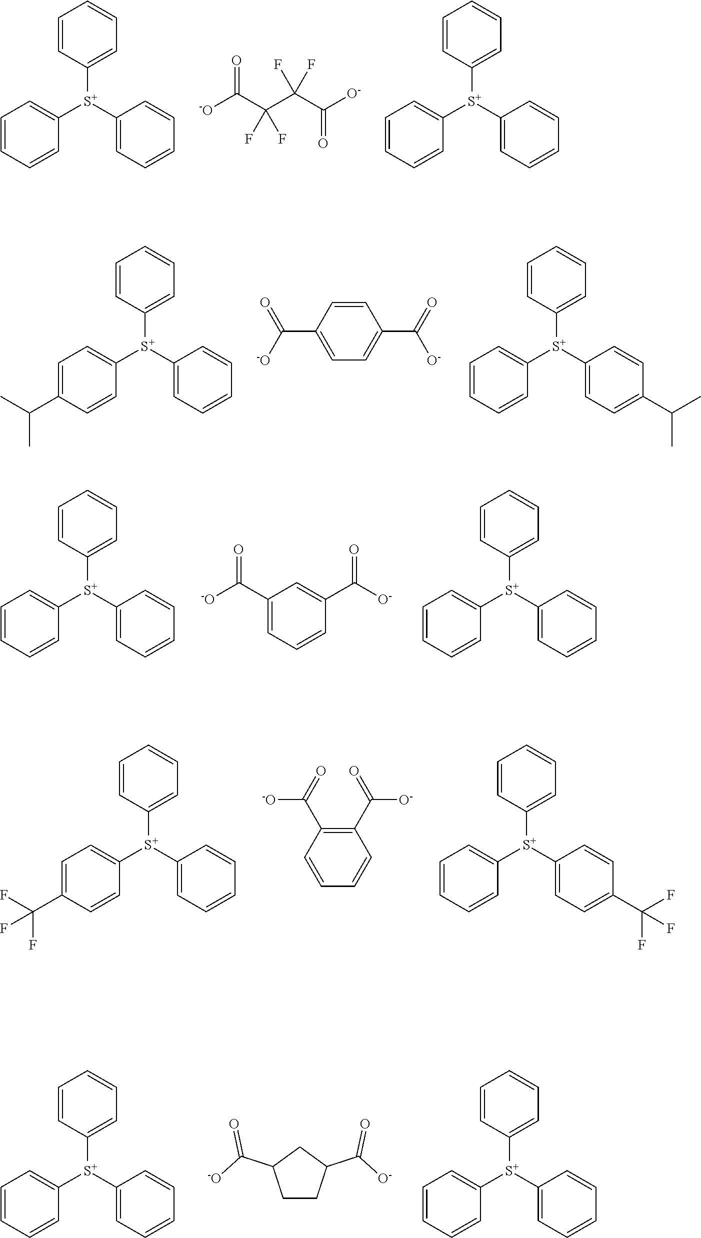

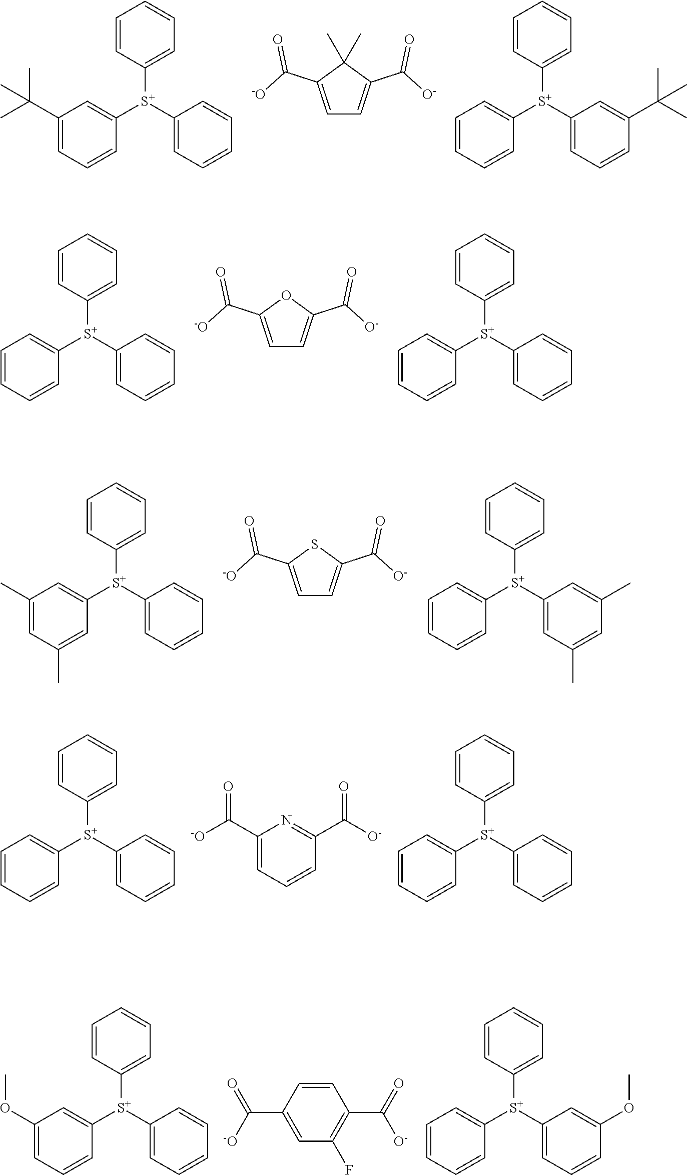

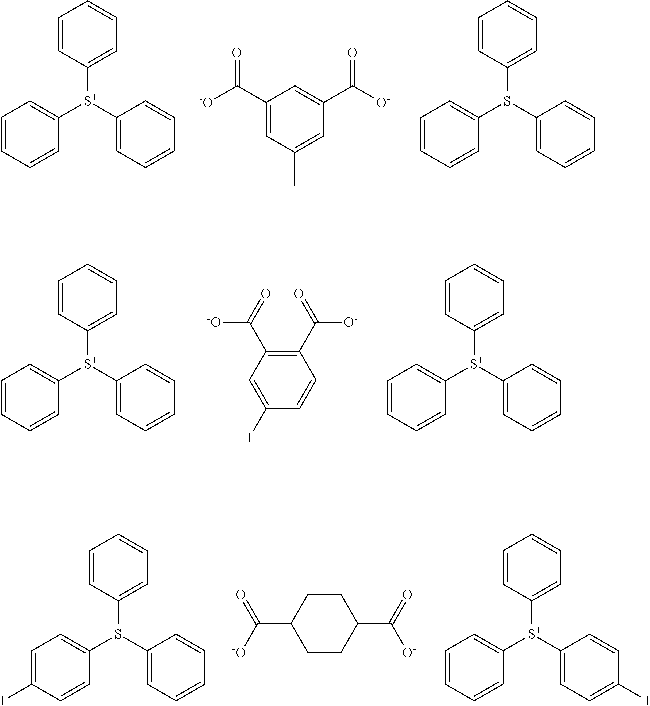

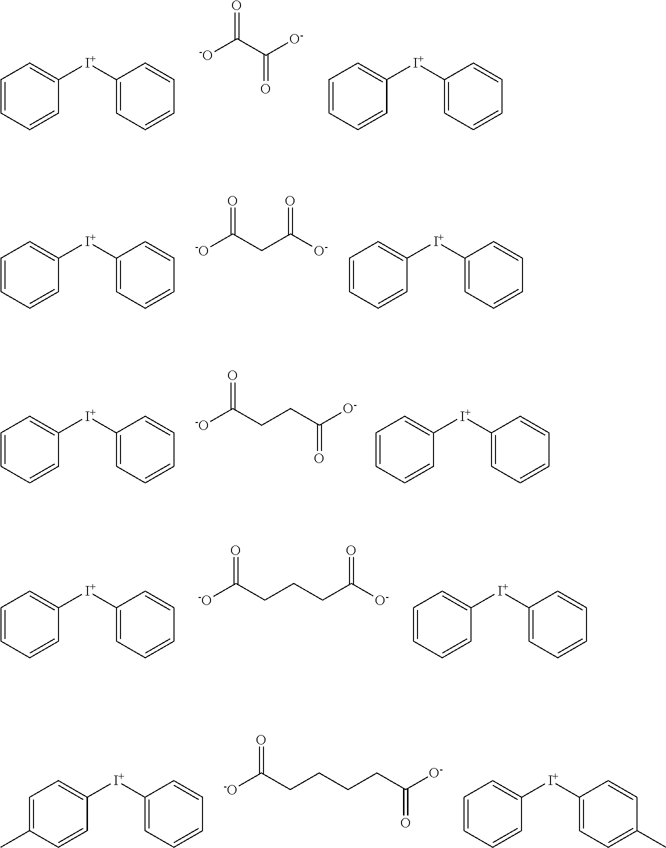

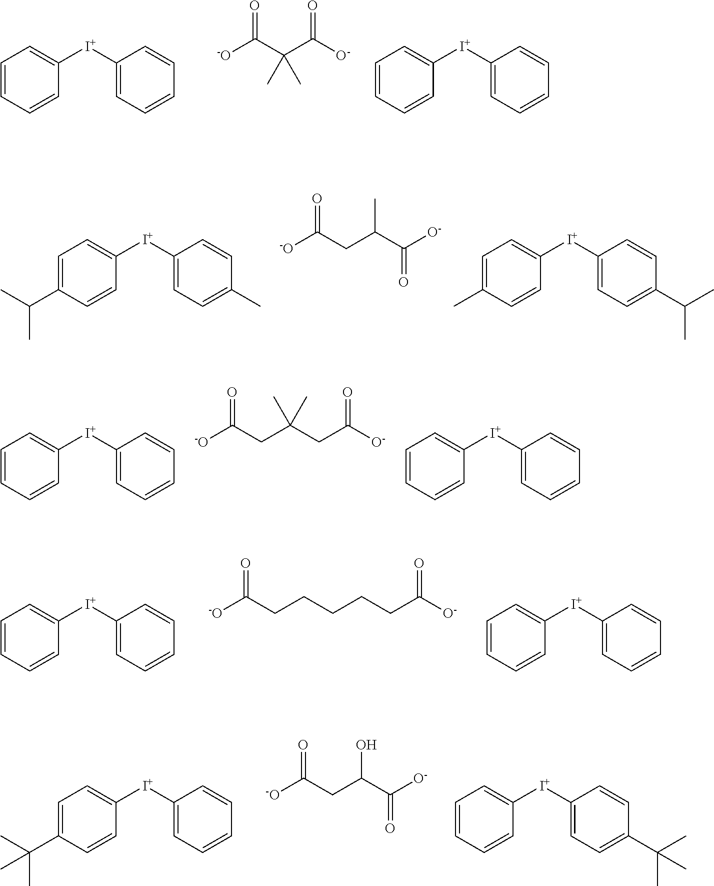

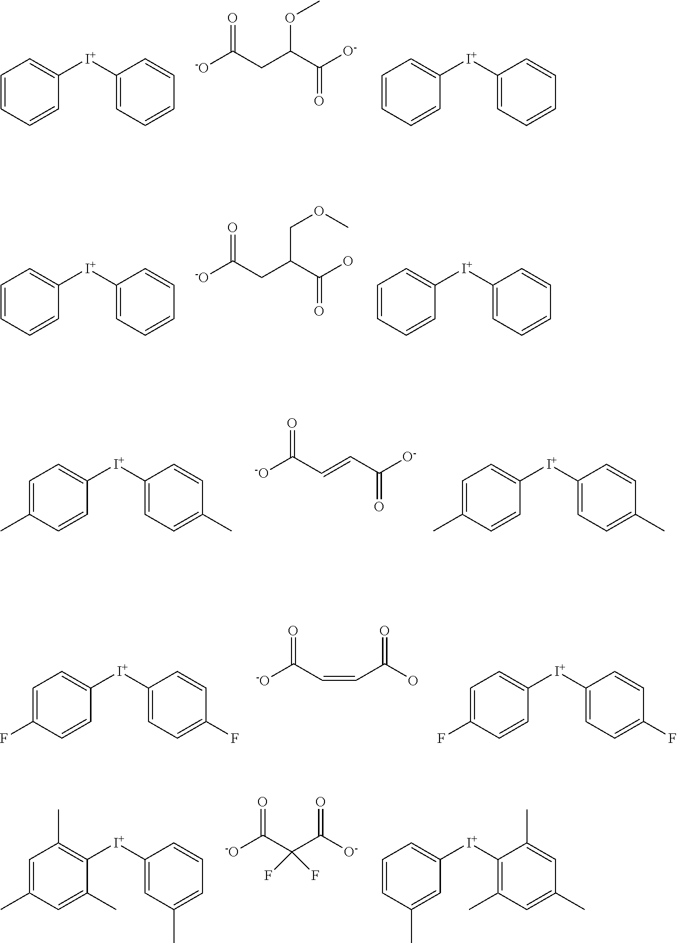

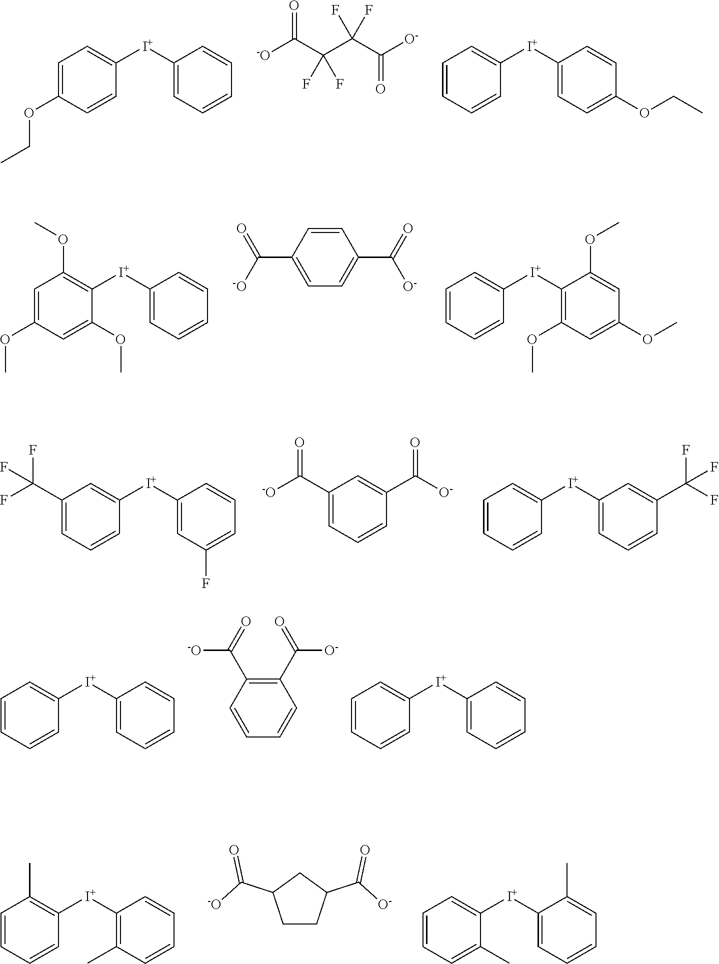

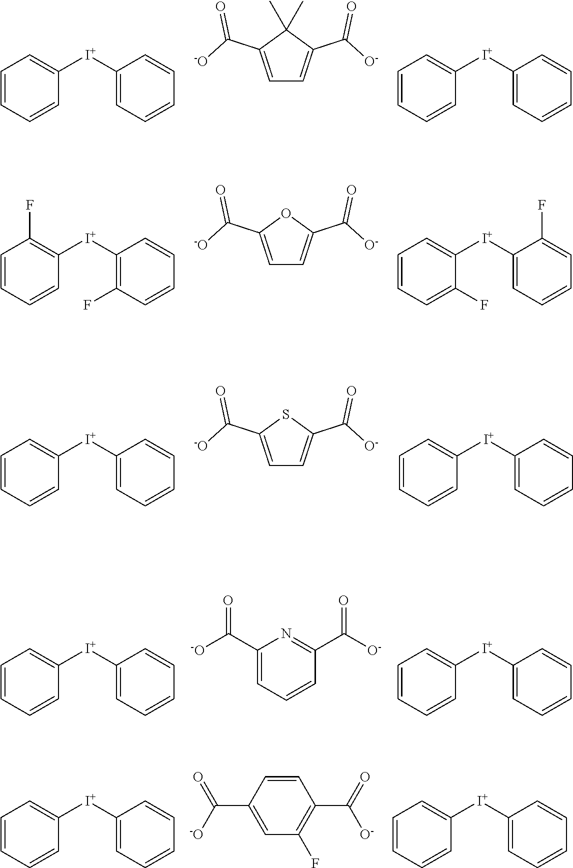

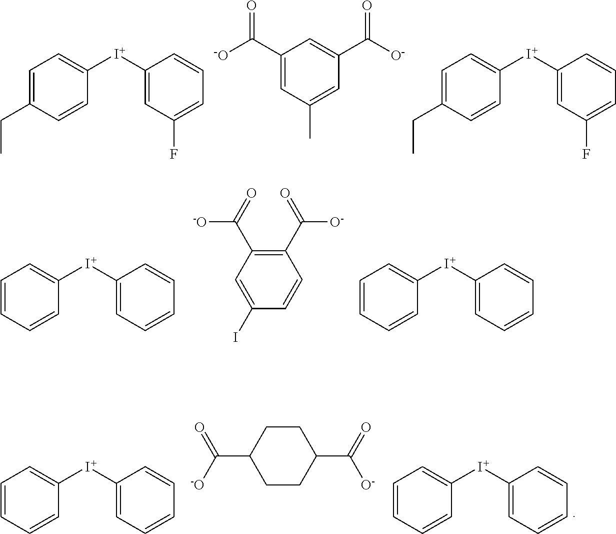

The salt compound may be included in an amount of about 0.01 to about 10 wt % based on 100 wt % of the semiconductor photoresist composition.

For example, the salt compound may be included in an amount of about 0.02 to about 10 wt %, about 0.03 to about 10 wt %, or about 0.05 to about 10 wt % based on 100 wt % of the semiconductor photoresist composition.

The organometallic compound may be included in an amount of about 0.5 wt % to about 30 wt % based on 100 wt % of the semiconductor photoresist composition.

A semiconductor photoresist composition according to some example embodiments can improve the sensitivity of the photoresist by including the salt compound in the above content ranges.

The organometallic compound may be an organotin compound including at least one selected from among an organooxy group and an organocarbonyloxy group.

For example, the organometallic compound may be represented by Chemical Formula 3.

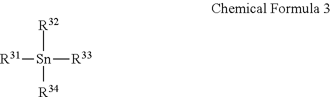

In Chemical Formula 3,
R³¹ is selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group,
R³² to R³⁴ are each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, alkoxy and/or aryloxy (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylamido and/or dialkylamido (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidato (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidinato (—NR^{h}C(NRⁱ)R^{j}, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylthio and/or arylthiol (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and/or a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and
at least one selected from among R³² to R³⁴ is selected from among alkoxy and aryloxy (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylamido and dialkylamido (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidato (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidinato (—NR^{h}C(NRⁱ)R^{j}, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylthio and arylthiol (—SRK, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and/or a thiocarboxyl group (—S(CO)R¹, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

At least one selected from among R³² to R³⁴ may be selected from among alkoxy and aryloxy (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

In embodiments, the compound represented by Chemical Formula 3 includes OR^{b} or —OC(═O)R^{c} as a ligand, so that a pattern formed using a semiconductor photoresist composition including it can exhibit excellent limit resolution. In embodiments, the ligand of —OR^{b} or —OC(═O)R^{c} may determine the solubility of the compound represented by Chemical Formula 3 in a solvent.

R³¹ may be a substituted or unsubstituted C1 to C8 alkyl group, a substituted or unsubstituted C3 to C8 cycloalkyl group, a substituted or unsubstituted C2 to C8 aliphatic unsaturated organic group including one or more double bonds or triple bonds, a substituted or unsubstituted C6 to C20 aryl group, a substituted or unsubstituted C4 to C20 heteroaryl group, a carbonyl group, ethoxy group, a propoxy group, or a combination thereof,

R^{b} may be a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof, and

R^{c} may be hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof.

R³¹ may be a methyl group, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, a formyl group, an acetyl group, a propanoyl group, a butanoyl group, a pentanoyl group, an ethoxy group, a propoxy group, or a combination thereof,

R^{b} may be an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof, and

R^{c} may be hydrogen, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof.

In embodiments, the organometallic compound may be represented by Chemical Formula 4 or Chemical Formula 5.

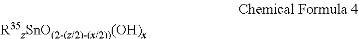

In Chemical Formula 4,

R³⁵ is a C1 to C31 hydrocarbyl group, 0<z≤2, and 0<(z+x)≤4;

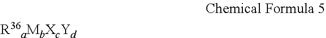

wherein, in Chemical Formula 5,
R³⁶ is a substituted or unsubstituted C1 to C20 alkyl group, a substituted or unsubstituted C3 to C20 cycloalkyl group, a substituted or unsubstituted C2 to C20 aliphatic unsaturated organic group including one or more double bonds or triple bonds, a substituted or unsubstituted C6 to C30 aryl group, a substituted or unsubstituted C4 to C30 heteroaryl group, a carbonyl group, an ethylene oxide group, propylene oxide group, or a combination thereof,
M is tin (Sn) or antimony (Sb),
X is sulfur(S), selenium (Se), or tellurium (Te),
Y is —OR^{m} or —OC(═O)Rⁿ,
R^{m} is a substituted or unsubstituted C1 to C20 alkyl group, a substituted or unsubstituted C3 to C20 cycloalkyl group, a substituted or unsubstituted C2 to C20 unsubstituted C6 to C30 aryl group, or a combination thereof,
Rⁿ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
a, b, c, and d are each independently an integer from 1 to 20.

The solvent included in the semiconductor photoresist composition according to some example embodiments may be an organic solvent, and may be for example aromatic compounds (e.g., xylene, toluene, and/or the like), alcohols (e.g., 4-methyl-2-pentenol, 4-methyl-2-propanol, 1-butanol, methanol, isopropyl alcohol, 1-propanol), ethers (e.g., anisole, tetrahydrofuran), esters (n-butyl acetate, propylene glycol monomethyl ether acetate, ethyl acetate, ethyl lactate), ketones (e.g., methyl ethyl ketone, 2-heptanone), or a mixture thereof, but is not limited thereto.

In some example embodiments, the semiconductor photoresist composition may further include a resin in addition to the aforementioned organometallic compound, salt compound, and solvent.

The resin may be a phenolic resin including at least one aromatic moiety listed in Group 2.

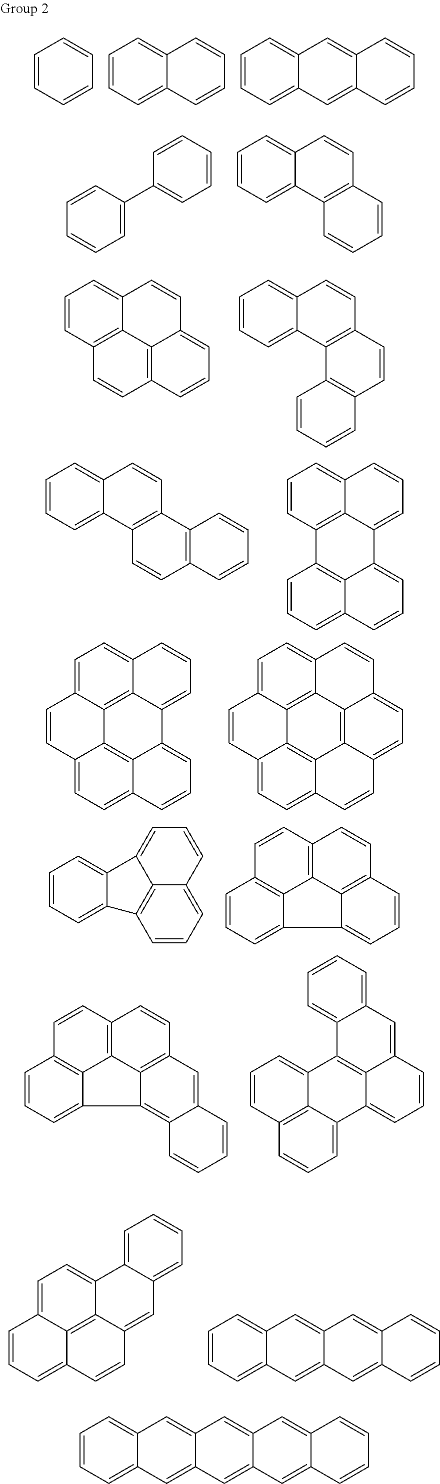

The resin may have a weight average molecular weight of about 500 to about 20,000.

5 The resin may be included in an amount of about 0.1 wt % to about 50 wt % based on a total amount of the semiconductor photoresist composition.

If (e.g., when) the resin is included within the above content range, it can have excellent etching resistance and heat resistance.

The semiconductor photoresist composition according to some example embodiments may be composed of the aforementioned organometallic compound, salt compound, solvent, and resin.

However, the semiconductor photoresist composition according to the aforementioned embodiments may further include additives in some embodiments. Examples of the additives may include a surfactant, a crosslinking agent, a leveling agent, an organic acid, quencher, or a combination thereof.

The surfactant may include for example an alkyl benzene sulfonate salt, an alkyl pyridinium salt, polyethylene glycol, a quaternary ammonium salt, or a combination thereof, but is not limited thereto.

The crosslinking agent may be for example a melamine-based crosslinking agent, a substituted urea-based crosslinking agent, an acryl-based crosslinking agent, an epoxy-based crosslinking agent, and/or a polymer-based crosslinking agent, but is not limited thereto. The crosslinking agent may have at least two crosslinking forming substituents, for example, a compound such as methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, trimethylpropane triglycidyl ether, 1,3-bis (glycidoxypropyl) tetramethyldisiloxane, methoxymethylated urea, butoxymethylated urea, methoxymethylated thiourea, and/or the like.

The leveling agent may be used for improving coating flatness during printing and may be any suitable commercially available leveling agent.

The organic acid may include p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, or a combination thereof, but is not limited thereto.

The quencher may be diphenyl (p-tolyl) amine, methyl diphenyl amine, triphenyl amine, phenylenediamine, naphthylamine, diaminonaphthalene, or a combination thereof.

A use amount of these other additives may be controlled depending on suitable or desired properties.

In embodiments, the semiconductor photoresist composition may further include a silane coupling agent as an adherence enhancer in order to improve a close-contacting force with the substrate (e.g., in order to improve adherence of the semiconductor photoresist composition to the substrate). The silane coupling agent may be for example a silane compound including a carbon-carbon unsaturated bond such as vinyltrimethoxysilane, vinyl triethoxysilane, vinyl trichlorosilane, vinyl tris (β-methoxyethoxy) silane; and/or 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyl diethoxysilane; trimethoxy [3-(phenylamino) propyl] silane, and/or the like, but is not limited thereto.

The semiconductor photoresist composition may be formed into a pattern having a high aspect ratio without a collapse. Accordingly, in order to form a fine pattern having a width of, for example, about 5 nm to about 100 nm, for example, about 5 nm to about 80 nm, for example, about 5 nm to about 70 nm, for example, about 5 nm to about 50 nm, for example, about 5 nm to about 40 nm, for example, about 5 nm to about 30 nm, or for example, about 5 nm to about 20 nm, the semiconductor photoresist composition may be used for a photoresist process using light in a wavelength range from about 5 nm to about 150 nm, for example, about 5 nm to about 100 nm, about 5 nm to about 80 nm, about 5 nm to about 50 nm, about 5 nm to about 30 nm, or about 5 nm to about 20 nm. Accordingly, the semiconductor photoresist composition according to some example embodiments may be used to realize extreme ultraviolet lithography using an EUV light source of a wavelength of about 13.5 nm.

According to some example embodiments, a method of forming patterns using the aforementioned semiconductor photoresist composition is provided. For example, the manufactured pattern may be a photoresist pattern.

The method of forming patterns according to some example embodiments includes forming an etching-objective layer on a substrate, coating the semiconductor photoresist composition on the etching-objective layer to form a photoresist layer, patterning the photoresist layer to form a photoresist pattern and etching the etching-objective layer using the photoresist pattern as an etching mask.

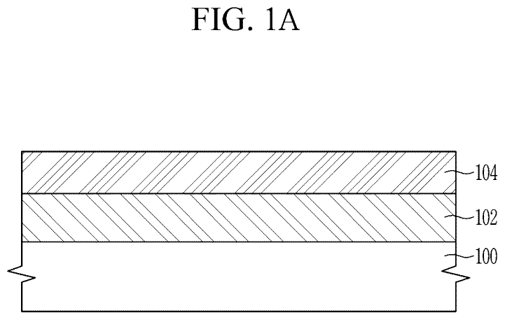

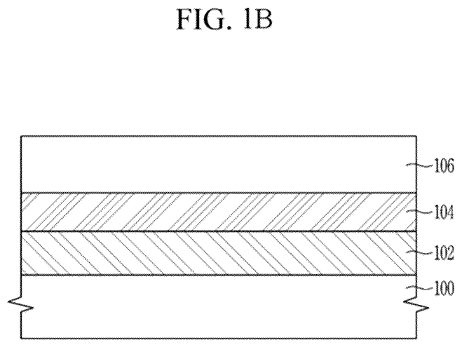

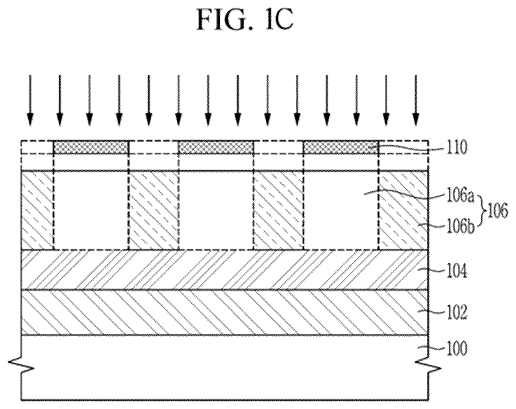

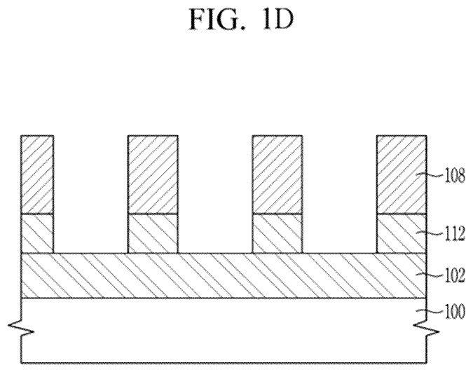

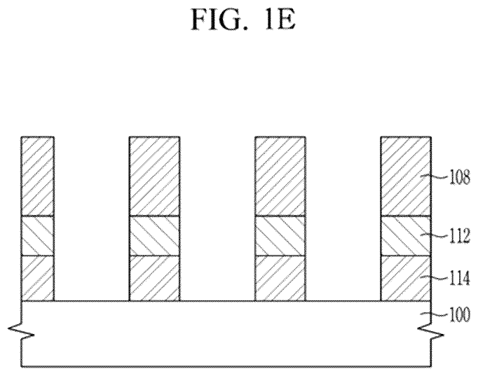

Hereinafter, a method of forming patterns using the semiconductor photoresist composition is described referring to FIGS. 1A-1E. FIGS. 1A-1E are cross-sectional views illustrating a method of forming patterns using a semiconductor photoresist composition according to some example embodiments.

Referring to FIG. 1A, an object to etch is prepared. The object to etch may be a thin film 102 formed on a semiconductor substrate 100. Hereinafter, the object to etch is limited to the thin film 102. A surface of the thin film 102 is washed to remove impurities and the like remaining thereon. The thin film 102 may be for example a silicon nitride layer, a polysilicon layer, and/or a silicon oxide layer.

Subsequently, the resist underlayer composition for forming a resist underlayer 104 is spin-coated on the surface of the washed thin film 102. However, embodiments are not limited thereto, and various suitable coating methods, for example a spray coating, a dip coating, a knife edge coating, a printing method, for example an inkjet printing and/or a screen printing, and/or the like may be used.

The coating process of the resist underlayer may be omitted, and hereinafter, a process including a coating of the resist underlayer is described.

Then, the coated composition is dried and baked to form a resist underlayer 104 on the thin film 102. The baking may be performed at about 100° C. to about 500° C., or, for example, about 100° C. to about 300° C.

The resist underlayer 104 is formed between the substrate 100 and a photoresist layer 106 and thus may prevent or reduce non-uniformity and pattern formability of a photoresist line width if (e.g., when) a ray reflected from on the interface between the substrate 100 and the photoresist layer 106 or a hardmask between layers is scattered into an unintended photoresist region.

Referring to FIG. 1B, the photoresist layer 106 is formed by coating the semiconductor photoresist composition on the resist underlayer 104. The photoresist layer 106 is obtained by coating the aforementioned semiconductor photoresist composition on the thin film 102 formed on the substrate 100 and then, curing it through a heat treatment.

In embodiments, the formation of a pattern by using the semiconductor photoresist composition may include coating the semiconductor photoresist composition on the substrate 100 having the thin film 102 through spin coating, slit coating, inkjet printing, and/or the like and then, drying it to form the photoresist layer 106.

The semiconductor photoresist composition has already been illustrated in more detail and will not be illustrated again.

Subsequently, a substrate 100 having the photoresist layer 106 is subjected to a first baking process. The first baking process may be performed at about 80° C. to about 120° C.

Referring to FIG. 1C, the photoresist layer 106 may be selectively exposed using a patterned mask 110.

For example, the exposure may use an activation radiation with light having a high energy wavelength such as EUV (extreme ultraviolet; a wavelength of about 13.5 nm), an E-Beam (an electron beam), and/or the like as well as light such as an i-line (a wavelength of about 365 nm), a KrF excimer laser (a wavelength of about 248 nm), an ArF excimer laser (a wavelength of about 193 nm), and/or the like.

In embodiments, light for the exposure according to some example embodiments may have a wavelength in a range from about 5 nm to about 150 nm and a high energy wavelength, for example, EUV (extreme ultraviolet; a wavelength of 13.5 nm), an E-Beam (an electron beam), and/or the like.

The exposed region 106b of the photoresist layer 106 has a different solubility from the unexposed region 106a of the photoresist layer 106 by forming a polymer by a crosslinking reaction such as condensation (e.g., a condensation reaction) between organometallic compounds.

Subsequently, the substrate 100 is subjected to a second baking process. The second baking process may be performed at a temperature of about 90° C. to about 200° C. The exposed region 106b of the photoresist layer 106 becomes easily indissoluble with respect to a developer due to the second baking process.

In FIG. 1D, the unexposed region 106a of the photoresist layer is dissolved and removed using the developer to form a photoresist pattern 108. In embodiments, the unexposed region 106a of the photoresist layer is dissolved and removed by using an organic solvent such as 2-heptanone and/or the like to complete the photoresist pattern 108 corresponding to the negative tone image.

As described above, a developer used in a method of forming patterns according to some example embodiments may be an organic solvent. The organic solvent used in the method of forming patterns according to some example embodiments may be for example ketones such as methylethylketone, acetone, cyclohexanone, 2-heptanone, and/or the like, alcohols such as 4-methyl-2-propanol, 1-butanol, isopropanol, 1-propanol, methanol, and/or the like, esters such as propylene glycol monomethyl ether acetate, ethyl acetate, ethyl lactate, n-butyl acetate, butyrolactone, and/or the like, aromatic compounds such as benzene, xylene, toluene, and/or the like, or a combination thereof.

However, the photoresist pattern according to some example embodiments is not necessarily limited to the negative tone image but may be formed to have a positive tone image. Herein, a developer used for forming the positive tone image may be a quaternary ammonium hydroxide composition such as tetraethylammonium hydroxide, tetrapropylammonium hydroxide, tetrabutylammonium hydroxide, or a combination thereof.

As described above, exposure to light having a high energy such as EUV (extreme ultraViolet; a wavelength of 13.5 nm), an E-Beam (an electron beam), and/or the like as well as light having a wavelength such as i-line (wavelength of about 365 nm), KrF excimer laser (wavelength of about 248 nm), ArF excimer laser (wavelength of about 193 nm), and the like may provide a photoresist pattern 108 having a width of a thickness of about 5 nm to about 100 nm. For example, the photoresist pattern 108 may have a width of a thickness of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

In embodiments, the photoresist pattern 108 may have a pitch of having a half-pitch of less than or equal to about 50 nm, for example less than or equal to about 40 nm, for example less than or equal to about 30 nm, for example less than or equal to about 20 nm, or for example less than or equal to about 15 nm, and a line width roughness of less than or equal to about 10 nm, less than or equal to about 5 nm, less than or equal to about 3 nm, or less than or equal to about 2 nm.

Subsequently, the photoresist pattern 108 is used as an etching mask to etch the resist underlayer 104. Through this etching process, an organic layer pattern 112 is formed. The organic layer pattern 112 also may have a width corresponding to that of the photoresist pattern 108.

Referring to FIG. 1E, the exposed thin film 102 is etched by applying the photoresist pattern 108 as an etching mask. As a result, the thin film is formed as a thin film pattern 114.

The etching of the thin film 102 may be for example dry etching using an etching gas and the etching gas may be for example CHF₃, CF₄, Cl₂, BCl₃ and/or a mixed gas thereof.

In the exposure process, the thin film pattern 114 formed by using the photoresist pattern 108 formed through the exposure process performed by using an EUV light source may have a width corresponding to that of the photoresist pattern 108. For example, the thin film pattern 114 may have a width of about 5 nm to about 100 nm which is equal to that of the photoresist pattern 108. For example, the thin film pattern 114 formed by using the photoresist pattern 108 formed through the exposure process performed by using an EUV light source may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, about 5 nm to about 20 nm, or, for example, a width of less than or equal to about 20 nm, like that of the photoresist pattern 108.

Hereinafter, embodiments of the present disclosure will be described in more detail through examples of the preparation of the aforementioned semiconductor photoresist composition. However, the present disclosure is technically not restricted by the following examples.

### Synthesis of Organometallic Compounds

### Synthesis Example 1

40.7 g of t-butylSnPh₃ and 300 g of propionic acid were added to a 250 ml two-necked round-bottom flask and heated under reflux for 24 hours.

Unreacted propionic acid was removed under reduced pressure to obtain a compound represented by Chemical Formula 6.

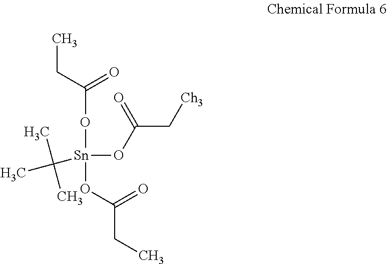

### Preparation of Semiconductor Photoresist Compositions

### Examples 1 to 4 and Comparative Examples 1 to 2

The organometallic compound represented by Chemical Formula 6 obtained in Synthesis Example 1 was dissolved in propylene glycol methyl ether acetate (PGMEA) at a concentration of 3%, salt compounds C1 to C4, and dicarboxylic acid compound C5 were added at the concentrations listed in Table 1 and dissolved, and then filtered through a 0.1 μm PTFE (polytetrafluoroethylene) syringe filter to prepare semiconductor photoresist compositions according to Examples and Comparative Examples. Each composition was coated on a silicon wafer to a thickness of 240 Å, and then a patterned film was manufactured through post-apply bake (PAB), exposure, post-exposure bake (PEB), and development processes.

TABLE 1

| | Organometallic compound | Salt compound |
|---|---|---|
| | (wt%) | (wt%) |
| Example 1 | Chemical Formula 6 | C1 |
| | (2.3) | 0.7 |
| Example 2 | | C2 |
| | | 0.7 |
| Example 3 | | C3 |
| | | 0.7 |
| Example 4 | | C4 |
| | | 0.7 |
| Comparative Example 1 | | — |
| Comparative Example 2 | | C5 |
| | | 0.7 |

C1: 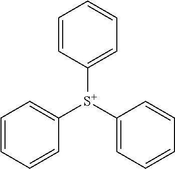 [SMILES: c1ccc([S+](c2ccccc2)c2ccccc2)cc1] 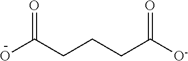 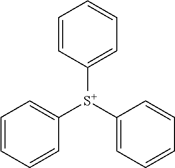 [SMILES: c1ccc([S+](c2ccccc2)c2ccccc2)cc1]
C2: 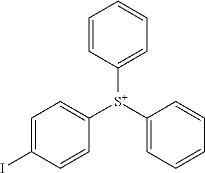 [SMILES: Ic1ccc([S+](c2ccccc2)c2ccccc2)cc1] 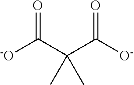 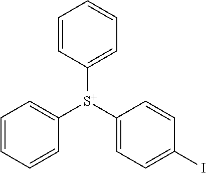 [SMILES: Ic1ccc([S+](c2ccccc2)c2ccccc2)cc1]
C3: 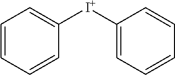 [SMILES: c1ccc([I+]c2ccccc2)cc1] 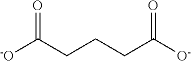 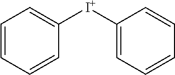 [SMILES: c1ccc([I+]c2ccccc2)cc1]
C4: 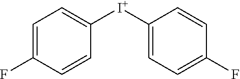 [SMILES: Fc1ccc([I+]c2ccc(F)cc2)cc1] 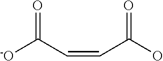 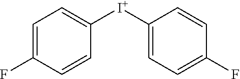 [SMILES: Fc1ccc([I+]c2ccc(F)cc2)cc1]
C5:

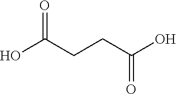

### Evaluation: Evaluation of Sensitivity and Line Edge Roughness (LER)

Each of the photoresist compositions according to the Examples and Comparative Examples was spin-coated for 30 seconds at 1500 rpm, respectively, on a 200 mm circular silicon wafer whose surface was deposited with hexamethyldisilazane HMDS, baked at 110° C. for 60 seconds (After application, it was baked (post-apply bake, PAB)), and left at room temperature (23±2° C.) for 30 seconds.

Subsequently, a straight line array of 50 circular pads each having a diameter of 500 μm was projected onto a wafer on which the composition for a photoresist was coated by using EUV light (Lawrence Berkeley National Laboratory Micro Exposure Tool, MET). Pad exposure time was adjusted to ensure that the EUV light in an increased dose was applied to each pad.

Then, the photoresist and substrate were exposed to temperatures at 160° C. on a hot plate for 120 seconds, and then baked. The baked film was developed with a PGMEA solvent to form a negative tone image. Finally, the obtained film was baked again at 150° C. for 2 minutes on the hot plate, completing the process.

The remaining photoresist thickness of the exposed pad was measured using an ellipsometer. The remaining thickness was measured for each exposure dose and then, graphed as a function to the exposure doses to measure sensitivity, and measuring LER was measured from an FE-SEM image to evaluate line edge roughness, and then, the sensitivity and the line edge roughness were evaluated according to the following criteria, and the results are shown in Table 2.

### Sensitivity Evaluation Criteria

A: less than 50 mJ/cm²
B: greater than or equal to 50 mJ/cm² and less than 55 mJ/cm²
C: greater than or equal to 55 mJ/cm² and less than 60 mJ/cm² LER Evaluation Criteria
∘: less than or equal to 2 nm
Δ: greater than 2 nm and less than or equal to 5 nm
X: greater than 5 nm

TABLE 2

| | Sensitivity | LER |
|---|---|---|
| Comparative Example 1 | C | X |
| Comparative Example 2 | B | X |
| Example 1 | B | Δ |
| Example 2 | A | Δ |
| Example 3 | A | ◯ |
| Example 4 | A | ◯ |

From the results in Table 2, the patterns formed using the semiconductor photoresist compositions according to Examples 1 to 4 exhibited superior sensitivity and LER characteristics compared to Comparative Examples 1 and 2.

Hereinbefore, certain embodiments have been described and illustrated, however, it should be apparent to a person having ordinary skill in the art that the present disclosure is not limited to the embodiment as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims of the present disclosure, and equivalents thereof.

Description of symbols

| | |
|---|---|
| 100: substrate | 102: thin film |
| 104: resist underlayer | 106: photoresist layer |
| 106a: unexposed region | 106b: exposed region |
| 108: photoresist pattern | 112: organic layer pattern |
| 110: patterned mask | 114: thin film pattern |

What is claimed is:

1. A semiconductor photoresist composition, comprising:
an organometallic compound;
a salt compound comprising an anion represented by Chemical Formula 1; and
a solvent: 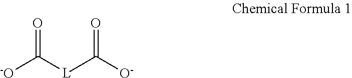
wherein, in Chemical Formula 1,
L is a single bond, a substituted or unsubstituted C1 to C10 alkylene group, a substituted or unsubstituted C2 to C10 alkenylene group, a substituted or unsubstituted C3 to C20 cycloalkylene group, a substituted or unsubstituted C3 to C20 cycloalkenylene group, a substituted or unsubstituted C6 to C30 arylene group, a substituted or unsubstituted C2 to C30 heteroarylene group, or a combination thereof.

2. The semiconductor photoresist composition as claimed in claim 1, wherein:
L is a single bond, a substituted or unsubstituted methylene group, a substituted or unsubstituted ethylene group, a substituted or unsubstituted propylene group, a substituted or unsubstituted butylene group, a substituted or unsubstituted pentylene group, a substituted or unsubstituted ethenylene group, a substituted or unsubstituted cyclopentylene group, a substituted or unsubstituted cyclohexylene group, a substituted or unsubstituted cyclopentenylene group, a substituted or unsubstituted cyclohexenylene group, a substituted or unsubstituted cyclopentadienylene group, a substituted or unsubstituted cyclohexadienylene group, a substituted or unsubstituted phenylene group, a substituted or unsubstituted furanylene group, a substituted or unsubstituted thiophenylene group, or a substituted or unsubstituted pyridinylene group.

3. The semiconductor photoresist composition as claimed in claim 1, wherein:
the anion represented by Chemical Formula 1 is selected from among those listed in Group I:

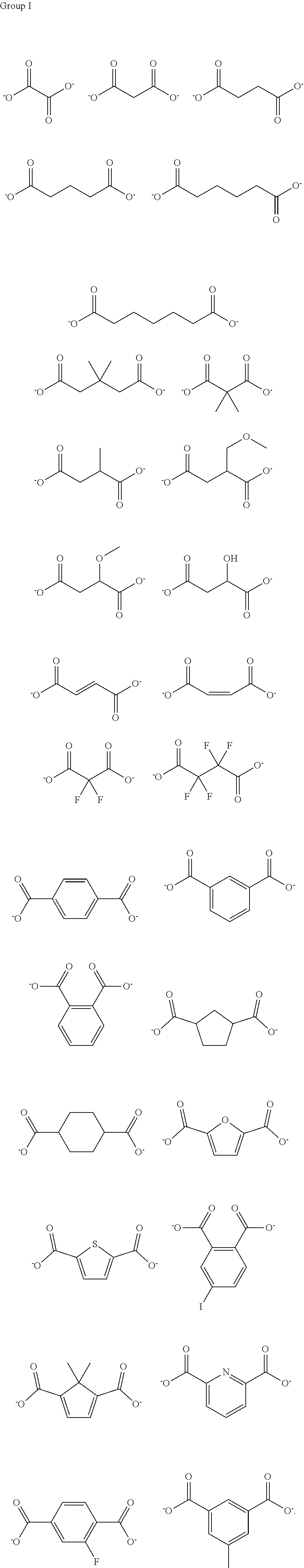

4. The semiconductor photoresist composition as claimed in claim 1, wherein:
the salt compound comprises a cation represented by Chemical Formula 2A or Chemical Formula 2B: 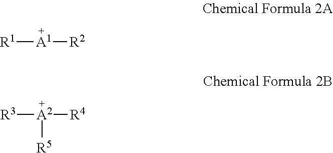
wherein, in Chemical Formula 2A and Chemical Formula 2B,
A¹ is F, Cl, Br, or I,
A² is O, S, Se, or Te, and
R¹ to R⁵ are each independently halogen, a hydroxy group, an ester group, a substituted or unsubstituted C1 to C20 alkyl group, a substituted or unsubstituted C1 to C20 alkoxy group, a substituted or unsubstituted C3 to C20 cycloalkyl group, a substituted or unsubstituted C2 to C20 aliphatic unsaturated organic group including one or more double bonds or triple bonds, a substituted or unsubstituted C6 to C30 aryl group, or a combination thereof.

5. The semiconductor photoresist composition as claimed in claim 4, wherein:
A¹ is I, and
A² is S.

6. The semiconductor photoresist composition as claimed in claim 4, wherein:
Chemical Formula 2A is represented by Chemical Formula 2A-1, and
Chemical Formula 2B is represented by Chemical Formula 2B-1: 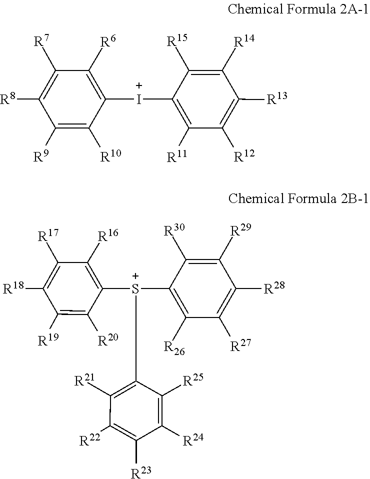
wherein, in Chemical Formula 2A-1 and Chemical Formula 2B-1,
R⁶ to R³⁰ are each independently hydrogen, a halogen, a hydroxy group, an ester group, a substituted or unsubstituted C1 to C20 alkyl group, a substituted or unsubstituted C1 to C20 alkoxy group, a substituted or unsubstituted C6 to C30 aryl group, or a combination thereof.

7. The semiconductor photoresist composition as claimed in claim 1, wherein:
the salt compound is selected from among the compounds listed in Group 1:

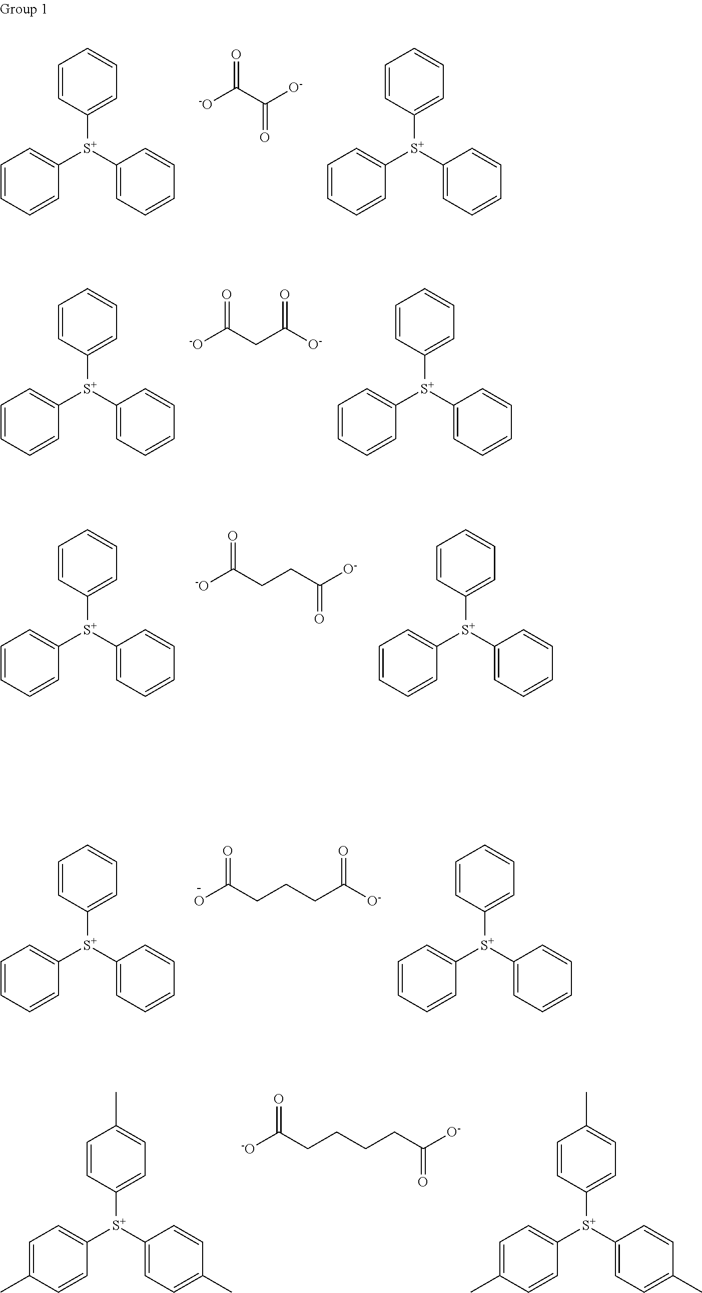

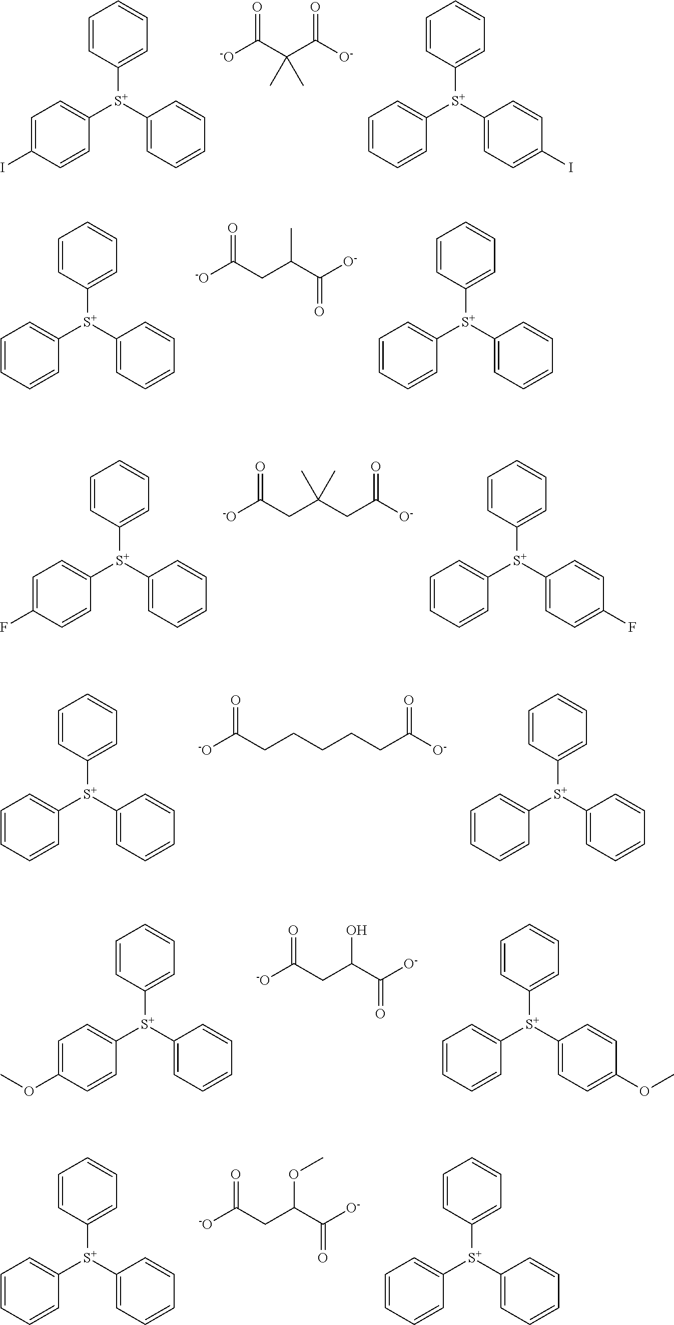

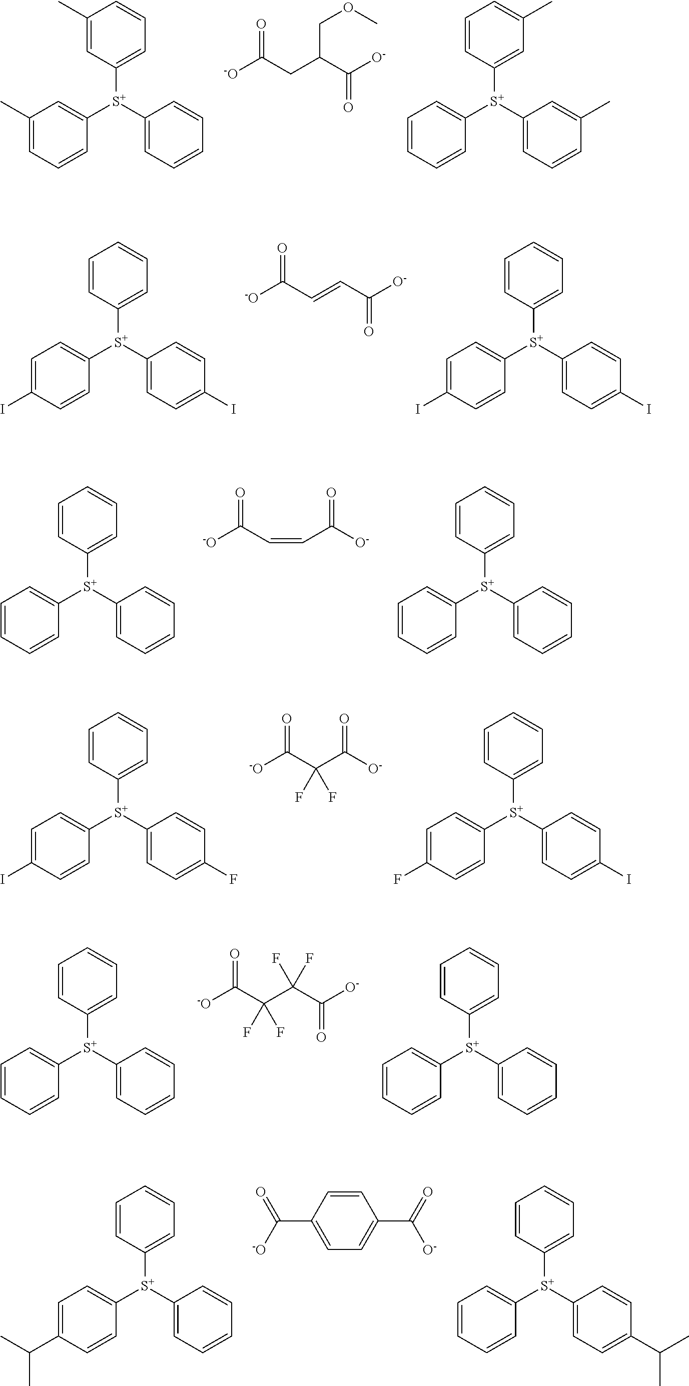

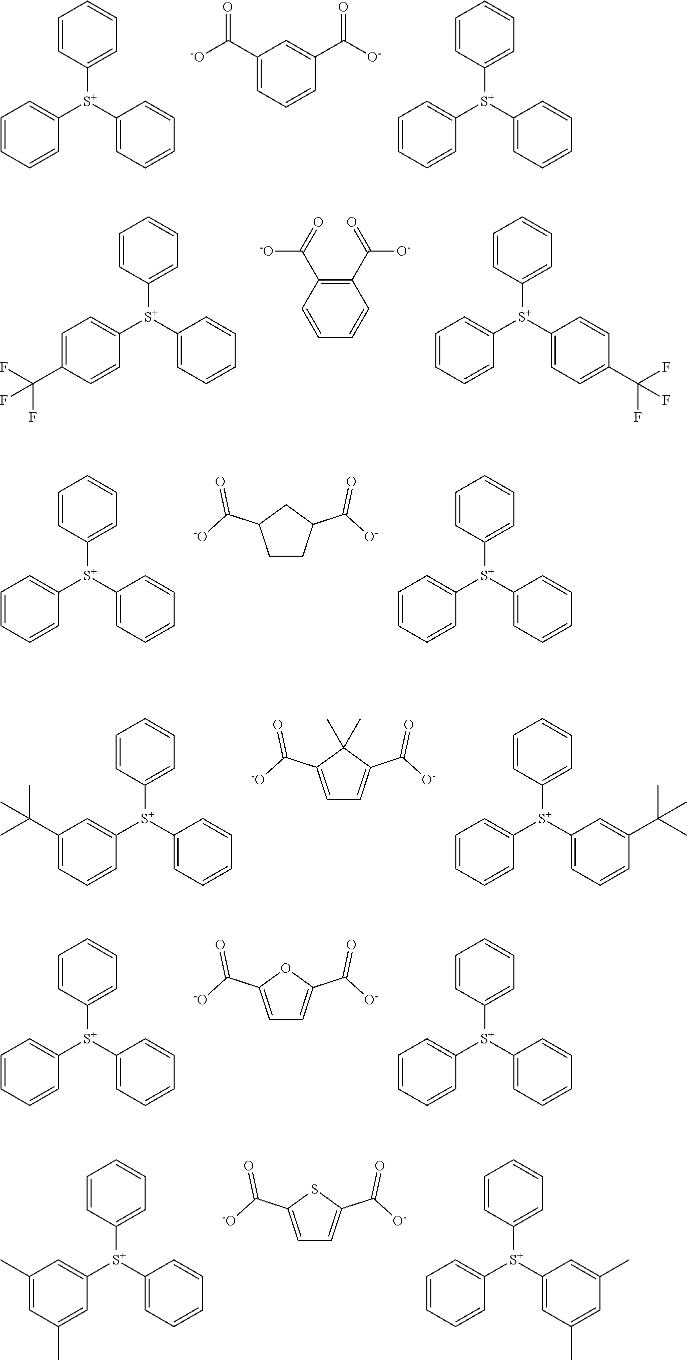

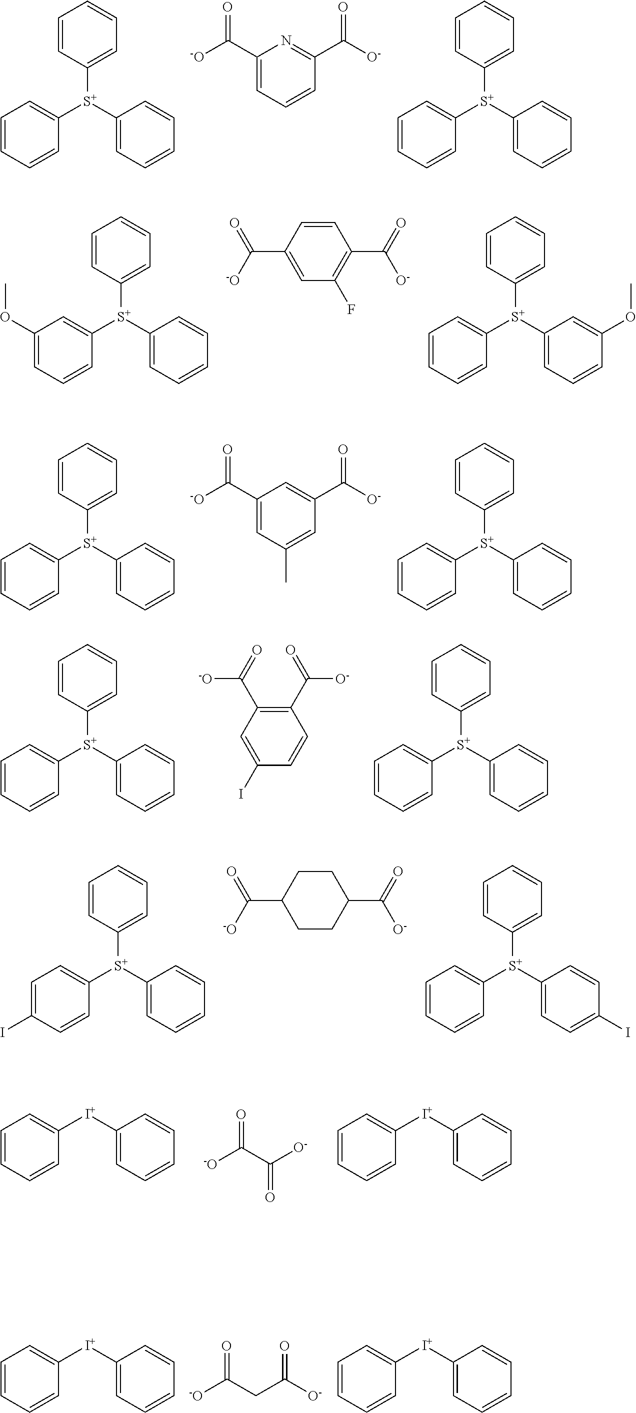

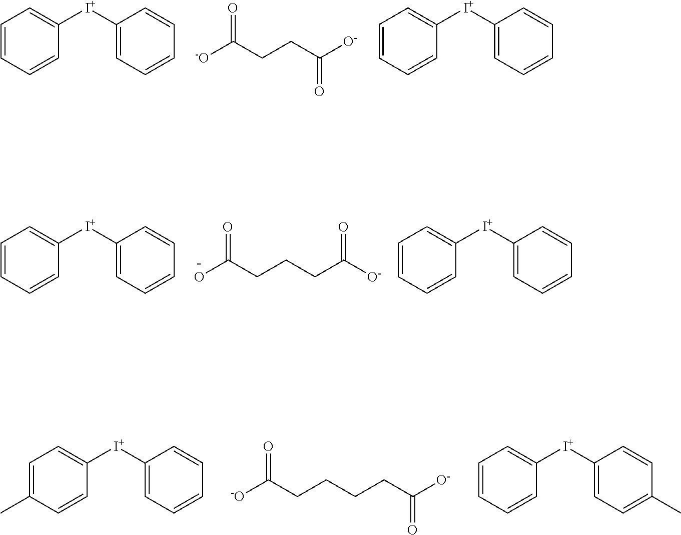

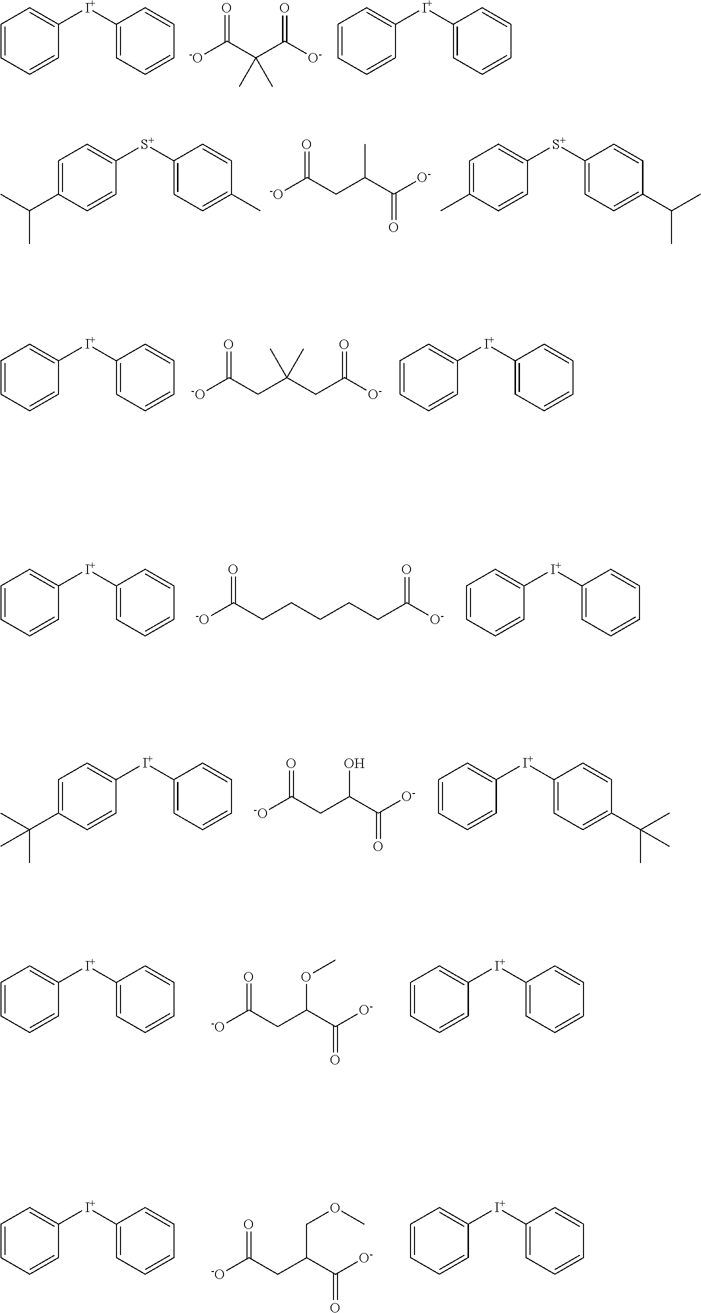

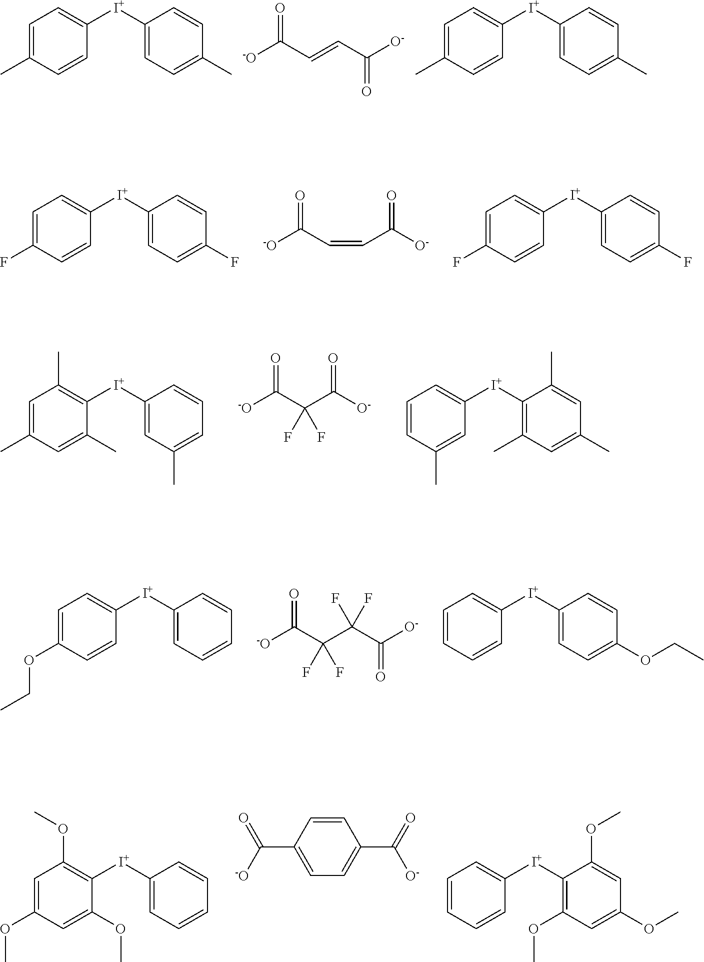

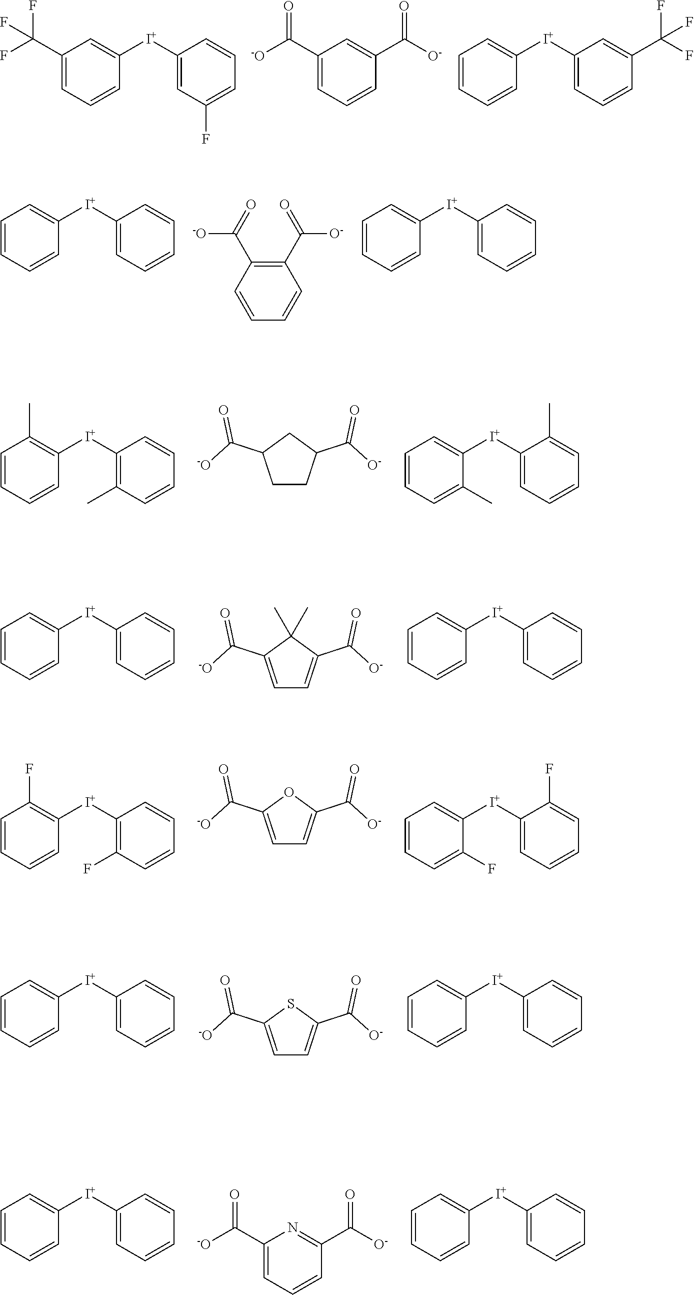

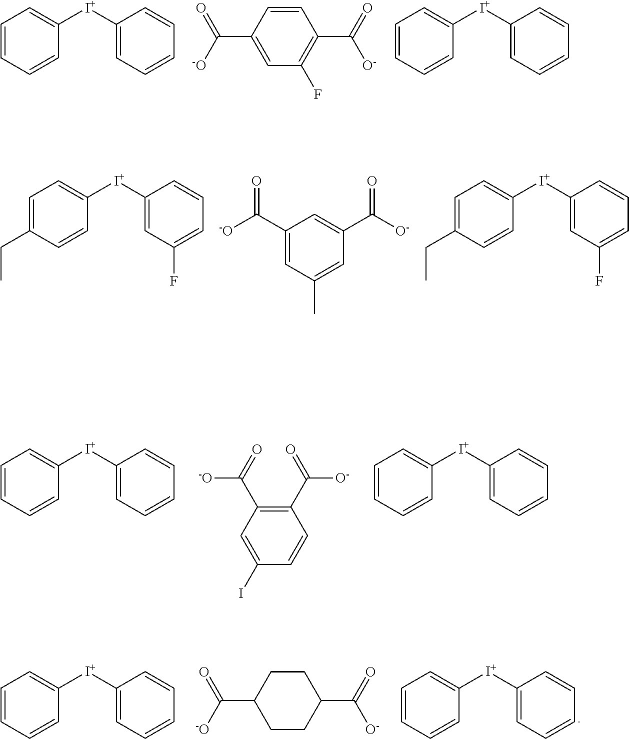

8. The semiconductor photoresist composition as claimed in claim 1, wherein:
the salt compound is included in an amount of about 0.01 wt % to about 10 wt % based on 100 wt % of the semiconductor photoresist composition.

9. The semiconductor photoresist composition as claimed in claim 1, wherein:
the organometallic compound is included in an amount of about 0.5 wt % to about 30 wt % based on 100 wt % of the semiconductor photoresist composition.

10. The semiconductor photoresist composition as claimed in claim 1, wherein:
the semiconductor photoresist composition further comprises an additive of a surfactant, a crosslinking agent, a leveling agent, an organic acid, a quencher, or a combination thereof.

11. The semiconductor photoresist composition as claimed in claim 1, wherein:
the organometallic compound is an organotin compound comprising at least one selected from among an organooxy group and an organocarbonyloxy group.

12. The semiconductor photoresist composition as claimed in claim 1, wherein:
the organometallic compound is represented by Chemical Formula 3: 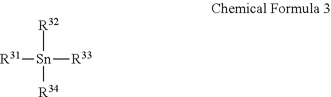
wherein, in Chemical Formula 3,
R³¹ is selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group,
R³² to R³⁴ are each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, alkoxy and/or aryloxy (—OR^{b}), wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 unsubstituted C6 to C30 aryl group, or a combination thereof), alkylamido or dialkylamido (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidato (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidinato (—NR^{h}C(NRⁱ)R^{j}, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylthio and/or arylthiol (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and/or a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and
at least one selected from among R³² to R³⁴ is alkoxy and aryloxy (—OR^{b}, wherein R^{b} is a substituted or unsubstituted C1 to C20 alkyl group, a substituted or unsubstituted C3 to C20 cycloalkyl group, a substituted or unsubstituted C2 to C20 unsubstituted C6 to C30 aryl group, or a combination thereof), a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylamido and dialkylamido (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidato (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidinato (—NR^{h}C(NRⁱ)R^{j}, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylthio and/or arylthiol (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

13. The semiconductor photoresist composition as claimed in claim 12, wherein:
at least one selected from among R³² to R³⁴ is selected from among alkoxy and aryloxy (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

14. The semiconductor photoresist composition as claimed in claim 13, wherein:
R³¹ is a substituted or unsubstituted C1 to C8 alkyl group, a substituted or unsubstituted C3 to C8 cycloalkyl group, a substituted or unsubstituted C2 to C8 aliphatic unsaturated organic group including one or more double bonds or triple bonds, a substituted or unsubstituted C6 to C20 aryl group, a substituted or unsubstituted C4 to C20 heteroaryl group, a carbonyl group, ethoxy group, a propoxy group, or a combination thereof,
R^{b} is a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof, and
R^{c} is hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof.

15. The semiconductor photoresist composition as claimed in claim 1, wherein:
the organometallic compound is represented by Chemical Formula 4 or Chemical Formula 5: 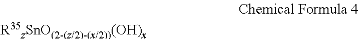
wherein, in Chemical Formula 4,
R³⁵ is a C1 to C31 hydrocarbyl group, 0<z≤2, and 0<(z+x)≤4; 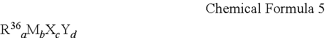
wherein, in Chemical Formula 5,
R³⁶ is a substituted or unsubstituted C1 to C20 alkyl group, a substituted or unsubstituted C3 to C20 cycloalkyl group, a substituted or unsubstituted C2 to C20 aliphatic unsaturated organic group including one or more double bonds or triple bonds, a substituted or unsubstituted C6 to C30 aryl group, a substituted or unsubstituted C4 to C30 heteroaryl group, a carbonyl group, an ethylene oxide group, propylene oxide group, or a combination thereof,
M is tin (Sn) or antimony (Sb),
X is sulfur(S), selenium (Se), or tellurium (Te),
Y is —OR^{m} or —OC(═O)Rⁿ,
R^{m} is a substituted or unsubstituted C1 to C20 alkyl group, a substituted or unsubstituted C3 to C20 cycloalkyl group, a substituted or unsubstituted C2 to C20 unsubstituted C6 to C30 aryl group, or a combination thereof,
Rⁿ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
a, b, c, and d are each independently an integer from 1 to 20.

16. A method of forming patterns, comprising:
forming an etching-objective layer on a substrate;
coating the semiconductor photoresist composition as claimed in claim 1 on the etching-objective layer to form a photoresist layer;
patterning the photoresist layer to form a photoresist pattern; and
etching the etching-objective layer using the photoresist pattern as an etching mask.
